(19) United States
(12) Patent Application Publication
(10) Pub. No.: US 2026/0323909 A1
(43) Pub. Date: Oct. 15, 2026

(54) Method Used In Forming Memory Circuitry

(71) Applicant: Micron Technology, Inc., Boise, ID (US)

(72) Inventors: Darwin Franseda Fan, Boise, ID (US); Adriel Jebin Jacob Jebaraj, Meridian, ID (US); Greg J. Light, Meridian, ID (US); Sang-Joon Park, Meridian, ID (US)

(73) Assignee: Micron Technology, Inc., Boise, ID (US)

(21) Appl. No.: 19/176,554

(22) Filed: Apr. 11, 2025

(51) Int. Cl. H10B 12/00

(52) U.S. Cl. CPC H10B 12/05; H10B 12/03; H10B 12/30

(57) ABSTRACT

A method used in forming memory circuitry comprises forming a stack comprising vertically-alternating semiconductive tiers and intervening tiers. A horizontally-elongated trench extends vertically through the stack. Semiconductive material in individual of the semiconductive tiers comprises a top, a bottom, and a trench end extending between the top and the bottom. The trench end in the individual semiconductive tiers is masked to leave the top and the bottom unmasked. Through the trench, the semiconductive material is removed from the unmasked top and the unmasked bottom while the trench end is at least initially masked to vertically thin the semiconductive material in the individual semiconductive tiers. Additional embodiments are disclosed.

### TECHNICAL FIELD

Embodiments disclosed herein pertain to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers (e.g., as part of memory-cell tiers) that extend into a connection region that may be a stair-step region. A stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-5 are diagrammatic cross-sectional views of a portion of a construction that will comprise circuitry in accordance with an embodiment of the invention.

FIGS. 6-25 are diagrammatic sequential sectional and/or enlarged views of the construction of FIGS. 3-5, or portions thereof or alternate and/or additional embodiments, in process in accordance with some embodiments of the invention.

### DETAILED DESCRIPTION OF EXAMPLE EMBODIMENTS

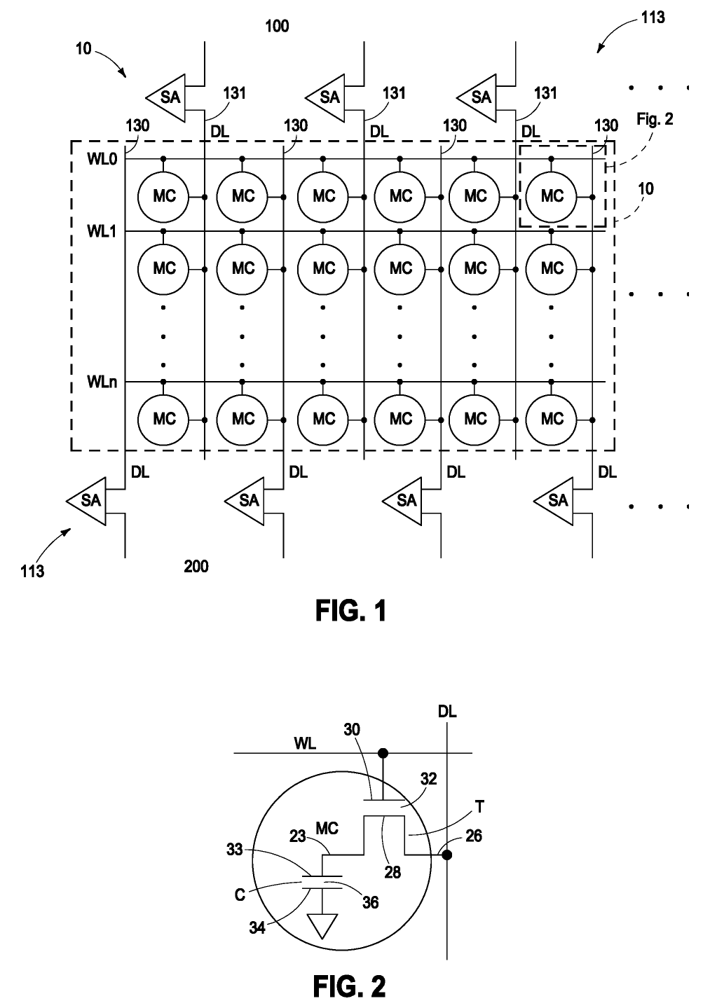

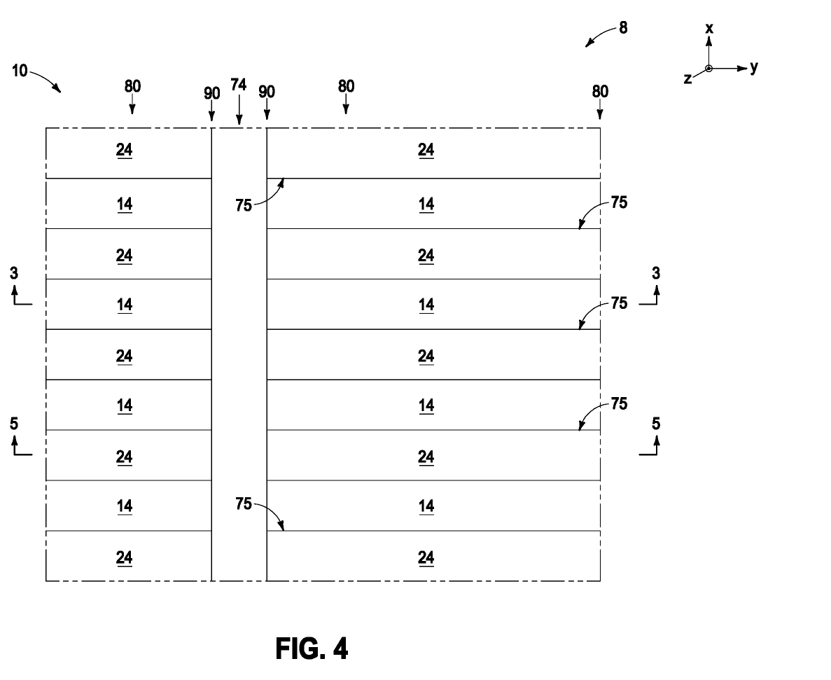

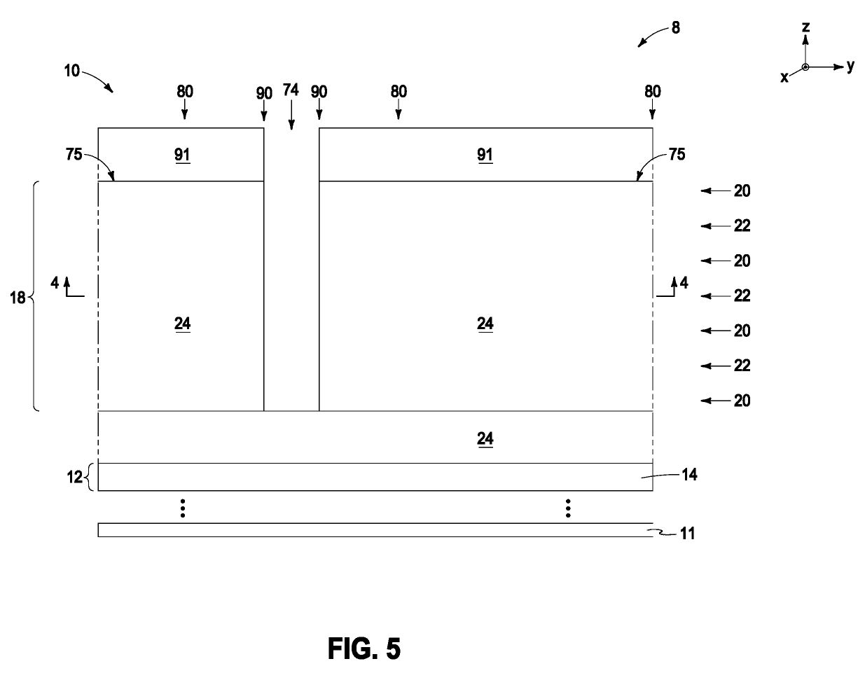

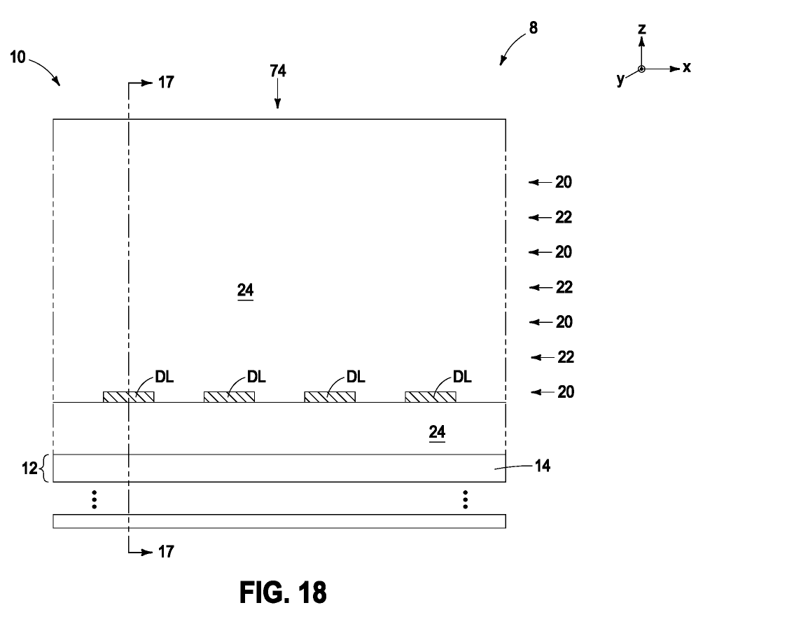

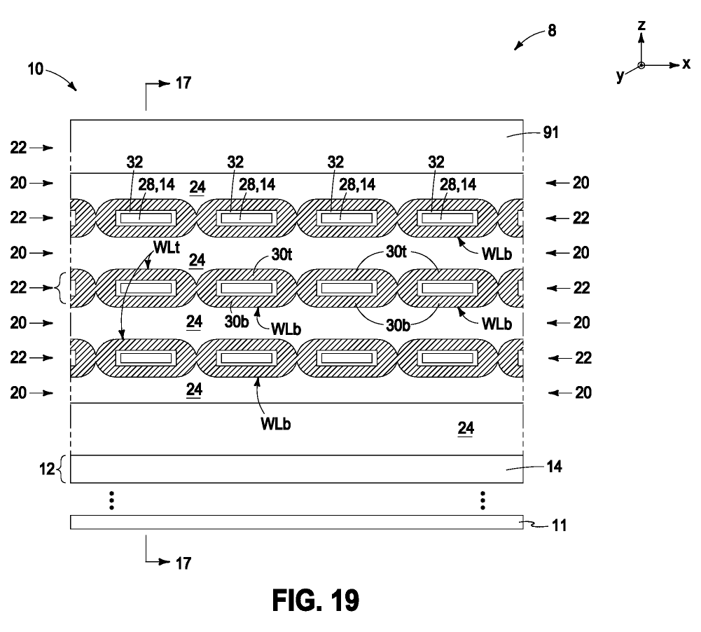

Embodiments of the invention encompass methods used in forming memory circuitry, for example memory circuitry (e.g., DRAM) having vertically-alternating tiers of insulative material and memory cells, with the memory cells individually comprising a capacitor and a horizontally-oriented transistor. Example method embodiments are first described with reference to FIGS. 1-25.

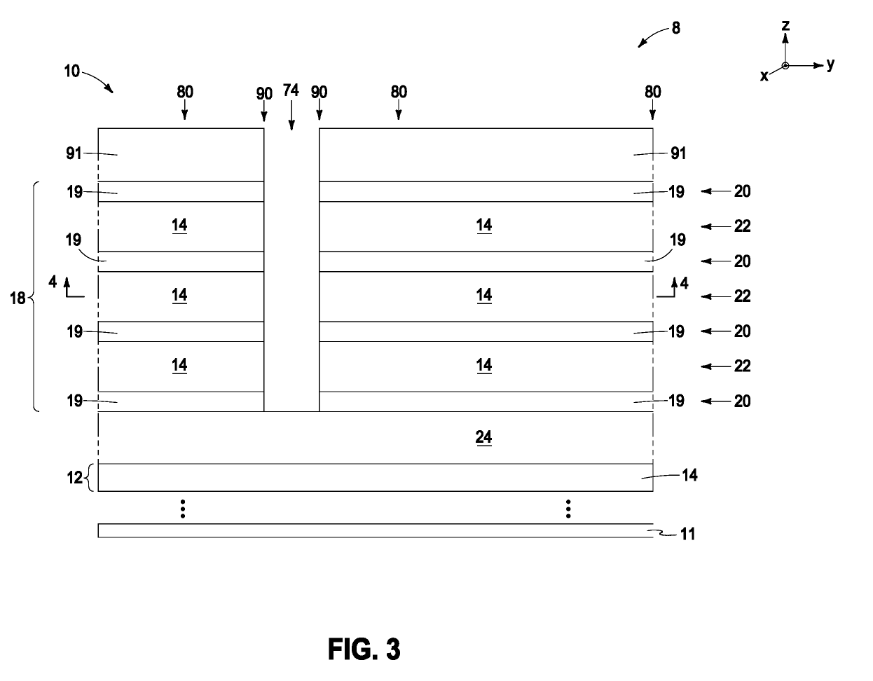

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIGS. 3+ have the wordlines/access lines running horizontally and the digitlines/sense lines running vertically.

Referring to FIGS. 3-5, and in some embodiments, a substrate construction 8 comprises an array or array area 10 that has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-5-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., semiconductive material 14 such as monocrystalline silicon) having insulative material 24 there-above (e.g., silicon dioxide).

A stack 18 has been formed above base substrate 11 and comprises vertically-alternating semiconductive tiers 22 and intervening tiers 20. Many more tiers 20 and 22 would be in stack 18 than shown. Example semiconductive tiers 22 comprise silicon 14 (e.g., elemental monocrystalline, epitaxial, and/or polycrystalline silicon and which may include one or more additional elements) and are in some embodiments referred to as silicon tiers 22. Example intervening tiers 20 comprise silicon-germanium material 19 (e.g., Si₁₋ₓGeₓ and which may include one or more additional elements). An example hardmask 91 (e.g., top and bottom silicon dioxide layers having a silicon nitride layer vertically there-between) is atop stack 18. In a finished memory-circuitry construction, and in one embodiment, memory cells (not-yet-shown) of the memory circuitry individually comprise a horizontal transistor (not-yet-shown) comprising part of silicon 14 in silicon tiers 22 and having a top gate (not-yet-shown), a bottom gate (not-yet-shown), channel material comprising silicon 14 between the top and bottom gates, a capacitor side (e.g., 80), and a digitline side (e.g., 90). Such memory cells will comprise a capacitor (not-yet-shown) on the capacitor side that is electrically coupled to one source/drain region of the horizontal transistor and part of a digitline (not-yet-shown) that is electrically coupled to another source/drain region of the horizontal transistor. In one embodiment and as shown, a horizontally-elongated digitline trench 74 (e.g., horizontally elongated in an x-direction) has been formed vertically through stack 18 on digitline side 90. In this document, a digitline trench is a trench in which digitlines have been or will be formed. Insulative walls 75 (e.g., comprising insulative material 24, e.g., silicon dioxide) will separate the channels and source/drain regions of immediately-x-direction-adjacent horizontal transistors in individual silicon tiers 22 in the finished construction (there being no other such noun [horizontal transistor] between those that are immediately-adjacent one another).

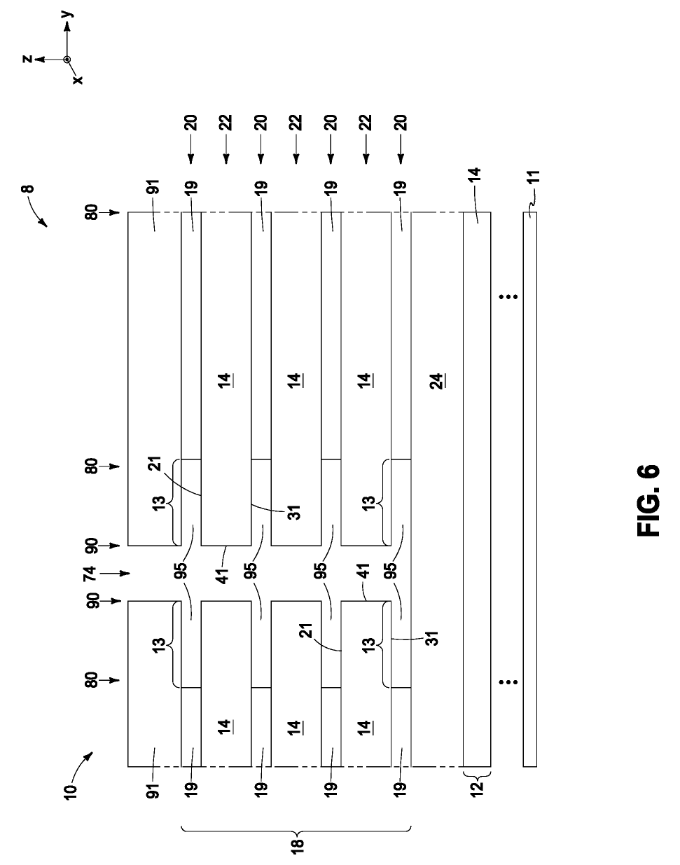

Referring to FIG. 6, a horizontal portion 13 of the layers comprising silicon-germanium material 19 has been removed from digitline side 90 (e.g., through digitline trench 74; e.g., by isotropic etching that may be selective or partially non-selective relative to silicon 14) to form void-space 95 (multiple being shown) between immediately-vertically-adjacent silicon tiers 22 and that extends horizontally to trench 74. Thus, and by way of example only, such processing is but one example of forming stack 18 to comprise vertically-alternating silicon/semiconductive tiers 22 and intervening tiers 20, the latter comprising void-space 95. Silicon 14 in individual silicon tiers 22 comprises a top 21, a bottom 31, and a digitline-trench end 41 (an end proximate and exposed to digitline trench 74) extending between top 21 and bottom 31.

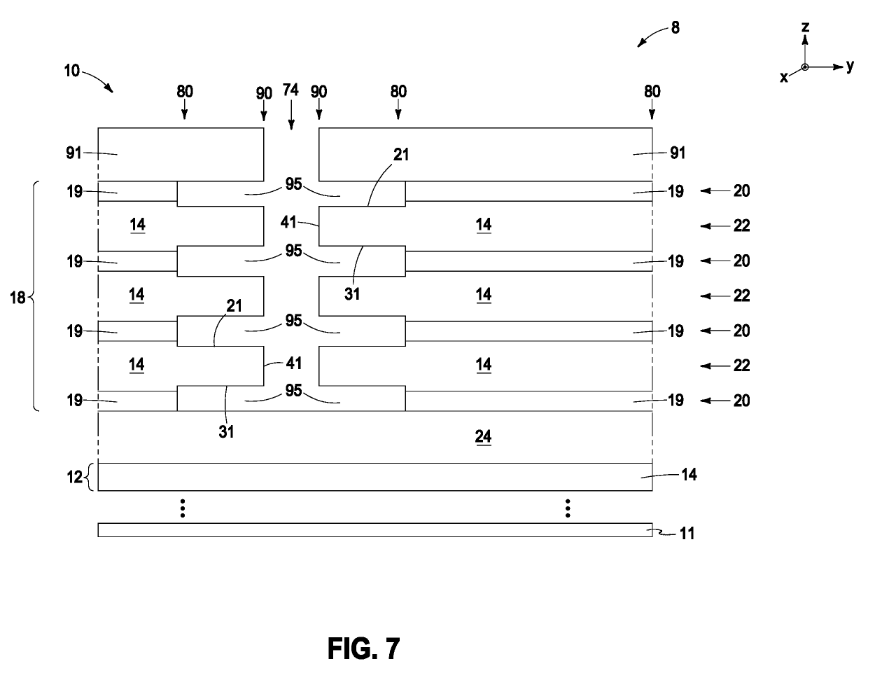

Referring to FIG. 7, and in one embodiment, some of silicon 14 has been removed from top 21 and bottom 31 (e.g., by isotropic etching using an ammonia hydroxide mix or tetramethylammonium hydroxide). Some of silicon 14 would also likely be removed from digitline-trench end 41 (not shown) by such removal from top 21 and bottom 31. Alternately, and by way of example only, the processing shown by FIG. 7 may not occur.

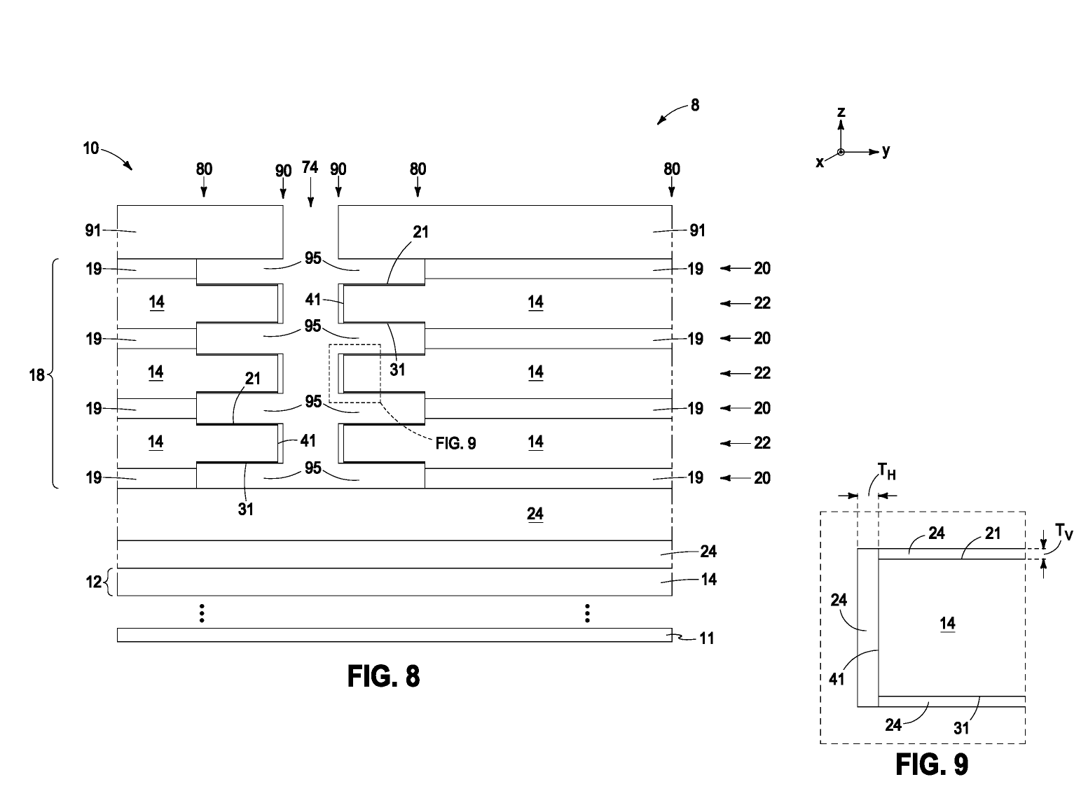

Referring to FIGS. 8 and 9, through the digitline trench 74, silicon 14 in individual silicon tiers 22 has been oxidized to form silicon dioxide 24 (e.g., masking material 24) on top 21, bottom 31, and digitline-trench end 41 of silicon 14, and such that silicon dioxide 24 is horizontally thicker (e.g., T_{H}) on digitline-trench end 41 than it is vertically thick (e.g., T_{V}) on each of top 21 and bottom 31. As an example, silicon 14 may constitute monocrystalline silicon where top 21 and bottom 31 each constitute a Miller Index lattice plane of 100, with digitline-trench end 41 constituting a Miller Index lattice plane of 110. Oxidizing such silicon 14 will result in T_{H} being greater than T_{V}, for example in some embodiments with T_{H} being 1.2 times, 1.4 times, 1.8 times, or more, greater than T_{V}. In one embodiment, the oxidizing comprises dry oxidizing (e.g., using O₂ and/or N₂O, 750°C to 1000° C, and 20 Torr to 760 Torr) and in another embodiment comprises wet oxidizing (e.g., using H₂O, or O₂ and H₂, 750°C to 1000°C, and 20 Torr to 760 Torr). Due to scale, silicon dioxide 24 that is on top 21 and bottom 31 is shown as a thicker, bold line in FIG. 8.

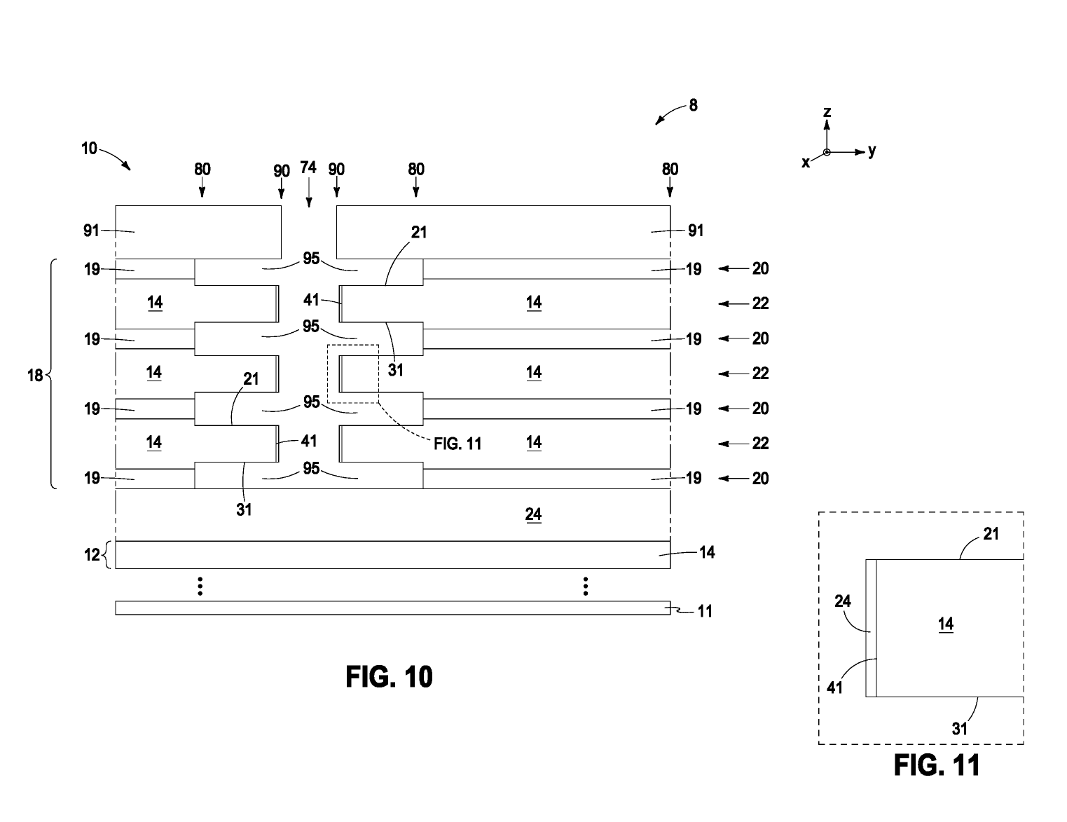

Referring to FIGS. 10 and 11, all of silicon dioxide 24 has been removed from top 21 and bottom 31 to leave at least some silicon dioxide 24 on digitline-trench end 41 (e.g., by timed isotropic vapor etching using HF from 1000:1 to 100:1 water to HF, where said HF is 49% by volume HF in water).

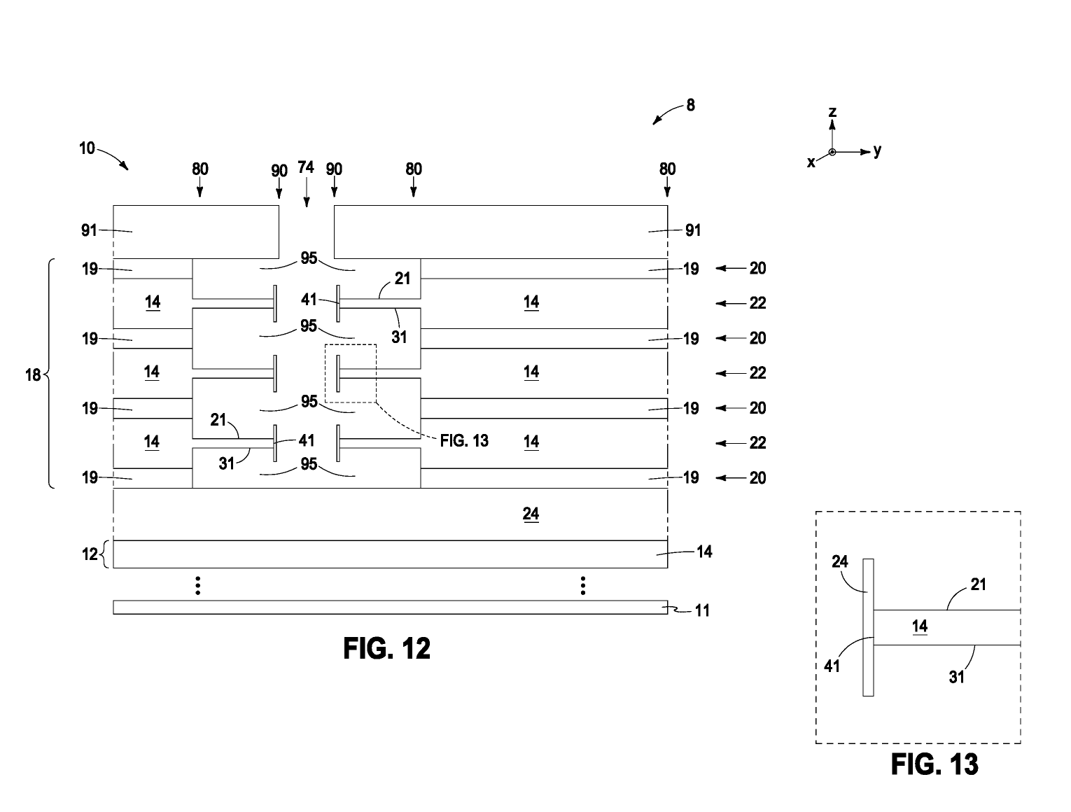

Referring to FIGS. 12 and 13, after the removing of silicon dioxide 24 in FIGS. 10 and 11 and through digitline trench 74, silicon 14 has been etched from top 21 and bottom 31 while digitline-trench end 41 is at least initially masked with silicon dioxide 24 to vertically thin silicon 14 in individual silicon tiers 22 (e.g., by isotropic etching using an ammonium peroxide mix or tetramethylammonium hydroxide (TMAH); e.g., or using a fluorocarbon such as CF₄, C₂F₆, C₃F₈, etc., a hydrofluorocarbon such as H₃CF, H₂CF₂, H₂C₂F₄, etc., and F₂ and that may or may not include one or more other non-fluorine containing substance[s]).

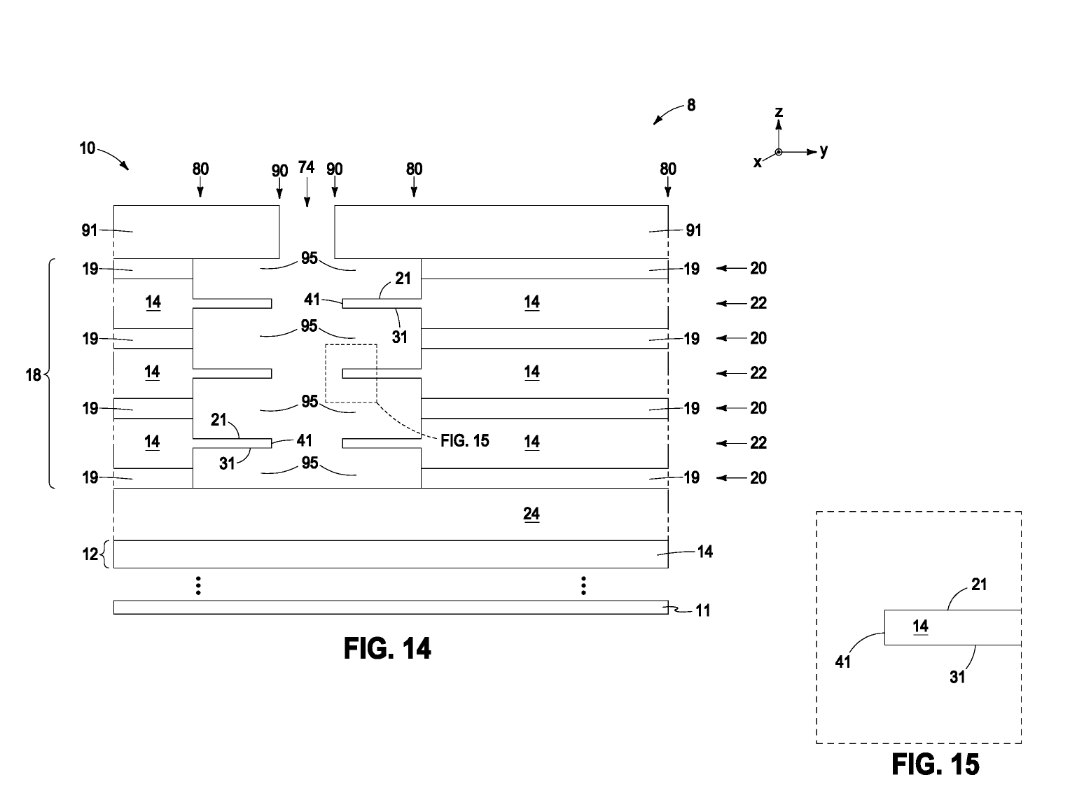

Referring to FIGS. 14 and 15, and in one embodiment, all remaining silicon dioxide 24 (such no longer being shown) has been removed from masking digitline-trench end 41 (e.g., by etching using HF). In one such embodiment and as shown, such removing of silicon dioxide 24 may etch some silicon 14 from digitline-trench end 41.

Depending on the method used in the processing shown going from FIGS. 10 and 11-14 and 15, processing might proceed directly from FIGS. 10 and 11-14 and 15 in a single processing step. For example, and by way of example only, in one embodiment the removing of semiconductive material 14/silicon 14 comprises etching using an etching chemistry and the removing of silicon dioxide 24 comprises etching using the same etching chemistry, with the etching of silicon dioxide 24 to remove all remaining of it from being over digitline-trench end 41 occurring during a latter part of the etching of semiconductive material 14 from unmasked top 21 and unmasked bottom 41 using such etching chemistry (e.g., in a single, continuous etching step). As an example, ammonium hydroxide will etch each of silicon and silicon dioxide, thus enabling a single etching chemistry and single etching step.

In an alternate embodiment and as is essentially shown by way of example in FIGS. 12-15, the removing of semiconductive material 14/silicon 14 comprises etching using a first etching chemistry (e.g., TMAH if silicon) and the removing of masking material 24/silicon dioxide 24 from digitline-trench end 41 comprises etching using a second etching chemistry (e.g., HF if silicon dioxide) that is different from the first etching chemistry. Some of masking material 24 might be etched during etching of semiconductive material 14/silicon 14 with the first etching chemistry. However, in such example, such is followed by etching at least a majority of masking material 24 (meaning more than 50% up to and including 100%) from digitline trench end 41 after the etching of at least a majority of semiconductive material 14/silicon 14 to vertically thin it. Semiconductor material 14/silicon 14 may be thicker immediately-adjacent masking material 24/silicon dioxide 24 in FIG. 13 (not shown) than distal therefrom if and after using TMAH.

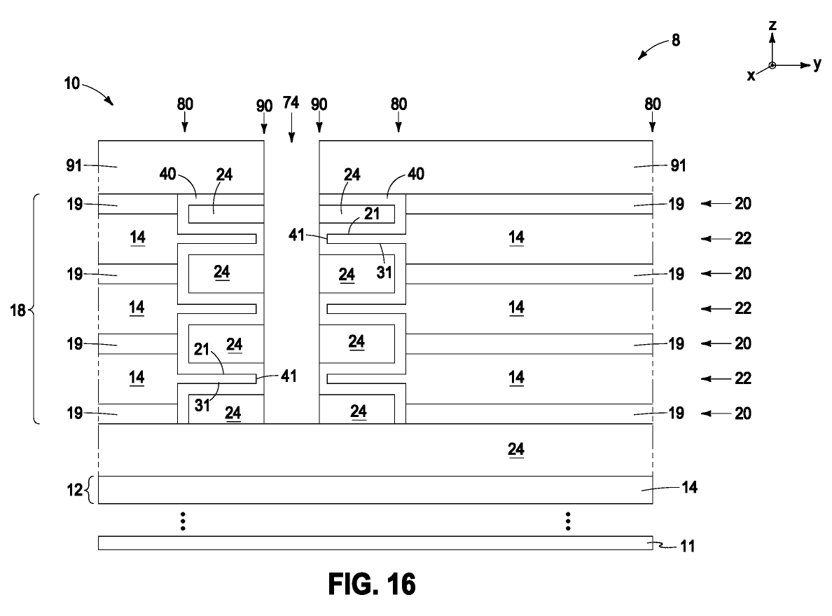

Referring to FIG. 16, and in one example, enlarged void-space 95 (FIG. 14) that is vertically between immediately-vertically-adjacent thinned silicon 14 has been lined with insulator material 40 (e.g., silicon nitride). Insulator material 40 may be deposited conformally within trench 74 and void-space 95 (FIG. 14) followed by removing (e.g., by anisotropic etch) of insulator material 40 from trench 74 as shown. Insulative material 24 has been formed in the space remaining after forming insulator material 40, followed by removing such insulative material 24 from digitline trench 74 (e.g., by anisotropic etch).

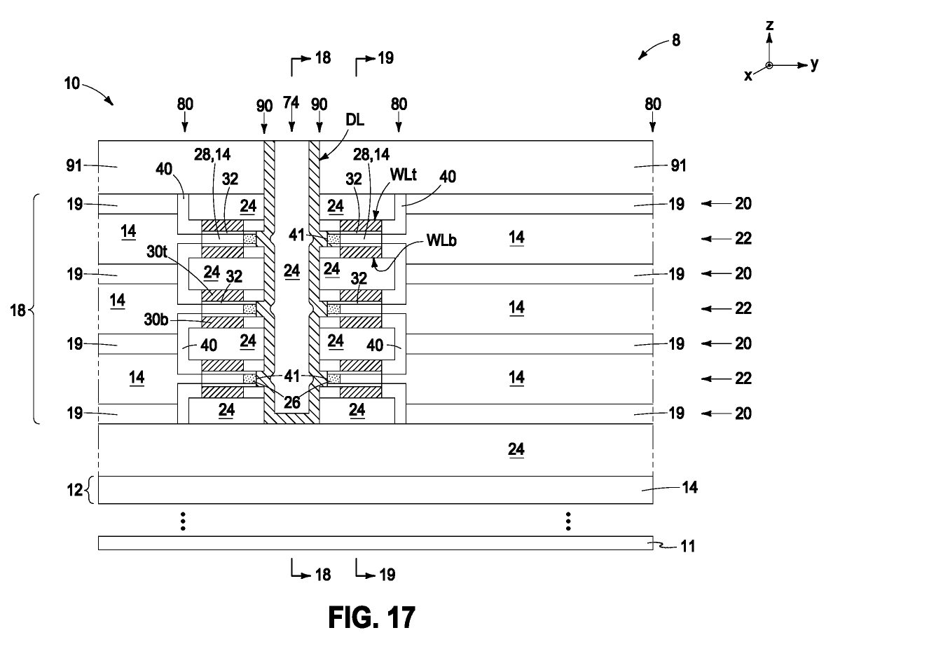

Referring to FIG. 17-19, a gate insulator 32 (e.g., silicon dioxide, hafnium oxide, silicon nitride, etc.) and a gate 30* of the horizontal transistor have been formed, with gate 30* comprising a top gate 30t and a bottom gate 30b (an * being used as a suffix to be inclusive of all such same-numerically-designated structures or portions thereof that may or may not have other suffixes). In one embodiment, top gate 30t is part of one of a plurality of top horizontal conductive access lines WLt and bottom gate 30b is part of one of a plurality of bottom horizontal conductive access lines WLb, with the one top horizontal conductive access line and the one bottom horizontal conductive access line together directly electrically coupling together multiple of the top and bottom gates of different ones of the horizontal transistors being formed that are in the same tier 22. By way of example only, top gate 30t and bottom gate 30b may be formed by etching back insulator material 40 of FIG. 16 selectively relative to silicon 14, gate insulator 32, and insulative material 24. This may be followed by deposition of conductive material of the top and bottom gates to within void-space left from such etching back of insulator material 40, followed by etching back such conductive material to produce the outlines of top and bottom gates 30t and 30b as shown. Then, more insulator material 40 may be deposited to fill remaining volume of the void-space on digitline side 90 of top and bottom gates 30t and 30b and to line and less-than-fill trench 74. Such insulator material may then be etched back to expose the thinned silicon 14 on digitline side 90. Silicon dioxide 24 that was removed from digitline-trench end 41 in FIG. 16 may alternately be removed here. Regardless, thinned silicon 14 has been conductively doped through trench 74 (e.g., by gas diffusion doping) to form digitline-side second source/drain regions 26. Digitlines DL have then been formed in digitline trench 74, with individual digitlines DL being directly against digitline-trench 41 end of vertically-thinned silicon 14 (e.g., directly against second source/drain regions 26). Insulative material 24 is formed in digitline trench 74, before or after forming digitlines DL, to isolate digitlines DL in the horizontal x-direction.

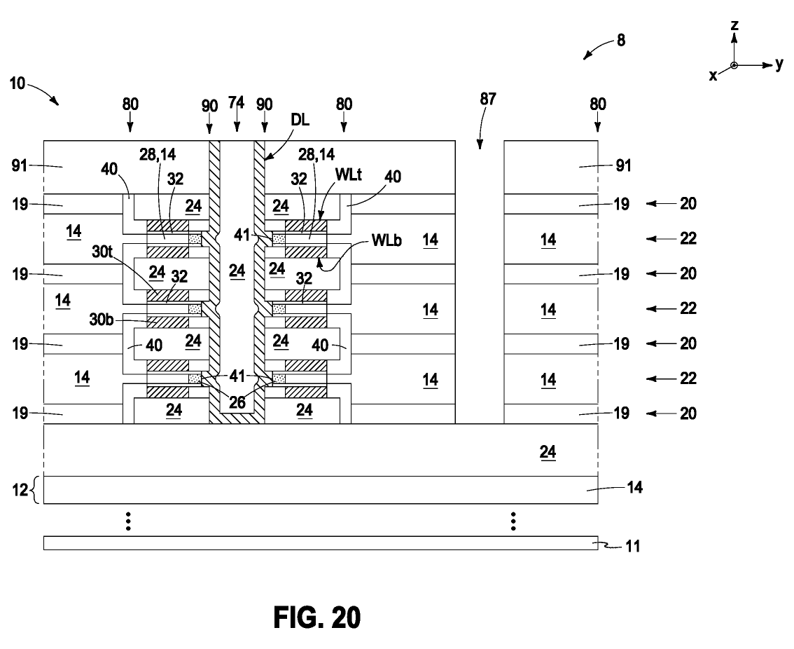

Referring to FIG. 20, a horizontally-elongated capacitor trench 87 has been formed through construction 8 on capacitor side 80 (e.g,, horizontally elongated in the x-direciton). In this document, a capacitor trench is a trench in which capacitors have been or will be formed. The capacitors being formed, by way of examples, may have their storage nodes being of a sideways pillar construction or being of a sideways container construction. The discussion proceeds initially with formation of a sideways pillar construction.

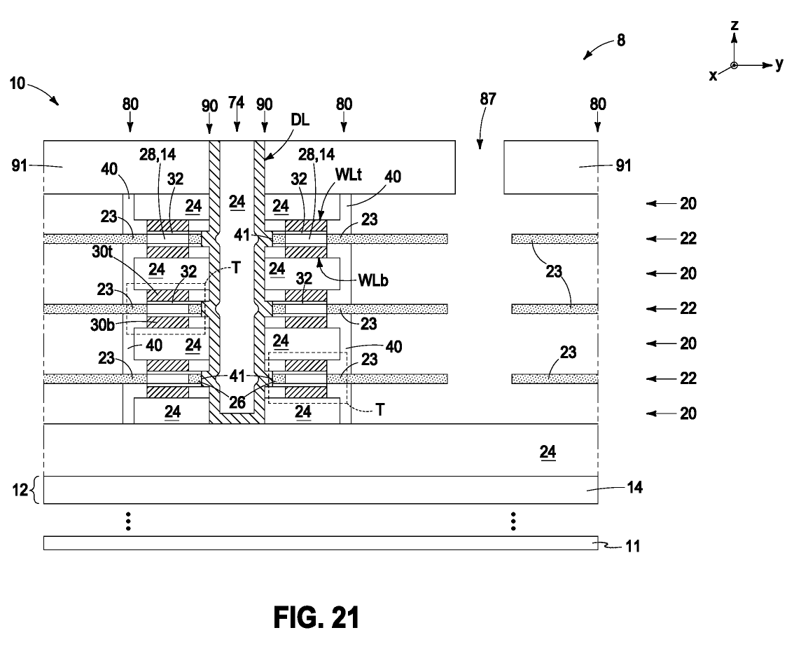

Referring to FIG. 21, and in one embodiment, several processing steps have occurred (e.g., analogously to those as described above with respect to FIGS. 6-15 with respect to digitline trench 74). Silicon-germanium material 19 (no longer shown) has been removed from capacitor side 80 (e.g., through capacitor trench 87) to form void-space (e.g., analogous to void-space 95 first-formed in FIG. 6) between immediately-vertically-adjacent silicon tiers 22 and that extends horizontally to trench 87. Silicon 14 in individual silicon tiers 22 comprises a top, a bottom, and a capacitor-trench end (an end proximate and exposed to capacitor trench 87) extending between the top and bottom (e.g., analogous to surfaces 21, 31, and 41 in FIG. 6). Then, through capacitor trench 87, silicon 14 in individual silicon tiers 22 was oxidized to form silicon dioxide (not shown) on the top, the bottom, and the capacitor-trench end of the silicon, with the silicon dioxide being horizontally thicker (e.g., T_{H}) on the capacitor-trench end than it is vertically thick (e.g., T_{V}) on each of the top and the bottom (e.g., analogous to FIGS. 8 and 9). Silicon 14 could have been thinned prior the oxidation (e.g., as was shown by FIG. 7 with respect to digitline trench 74). Regardless, then all of the silicon dioxide was removed from the top and the bottom to leave at least some silicon dioxide on the capacitor-trench end (e.g., analogous to FIGS. 10 and 11). Then, and through the capacitor-trench, the silicon was etched from the top and the bottom while the capacitor-trench end is at least initially masked with the silicon dioxide to vertically thin the silicon in the individual silicon tiers (e.g., analogous to FIGS. 12 and 13). In one embodiment and as shown, the silicon dioxide that was masking the capacitor end of the thinned silicon was removed (e.g., analogous to FIGS. 14 and 15, or by going directly from the processing shown by FIGS. 10 and 11 to that shown by FIGS. 14 and 15 in a single processing step as described above). Some of silicon 14 might be removed from the capacitor end of such silicon when removing such silicon dioxide (as shown). This was followed by conductively doping thinned silicon 14 through trench 87 (e.g., by gas diffusion doping) to form capacitor-side first source/drain regions 23, with a channel region 28/14 being horizontally between first and second source/drain regions 23 and 26, thus forming a horizontal transistor T. Regions 23 and 26 of different immediately-horizontally-x-direction-adjacent memory cells MC into and out of the plane of the page upon which FIG. 21 lies (e.g., in the x-direction) in a common tier 22 may be isolated relative one another by insulative material (not visible in FIG. 21). Any other attribute as described above with respect to thinned silicon 14 on digitline side 90 may apply to thinned silicon 14 on capacitor side 80.

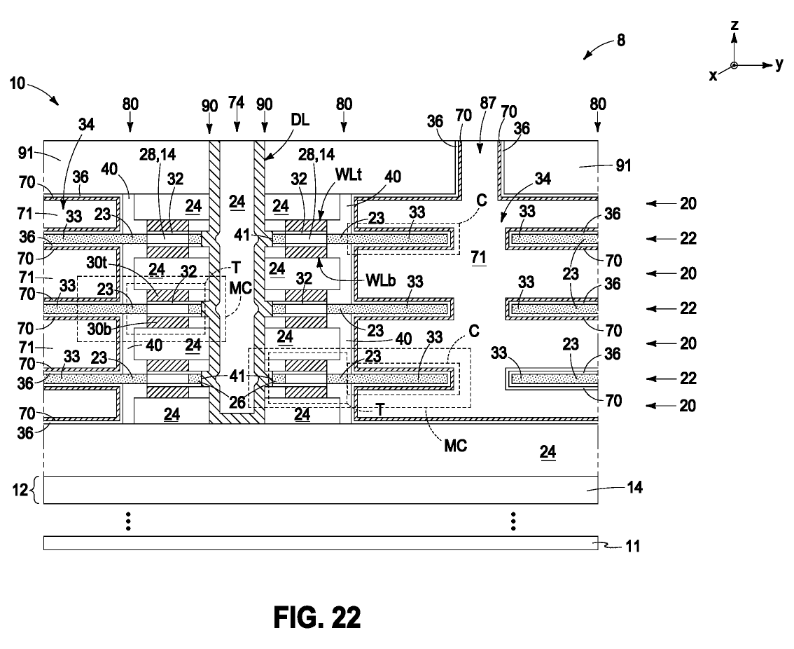

Referring to FIG. 22, a capacitor C has been formed in capacitor trench 87 directly electrically coupled to source/drain region 23. Example capacitor C comprises a first capacitor electrode 33 (e.g., a storage-node electrode in the form of a sideways pillar, e.g., integral with first source/drain region 23), a second capacitor electrode 34 (e.g., comprising conductive metal material 70 and conductively-doped polysilicon 71), and capacitor insulator 36 (e.g., dielectric and/or ferroelectric) there-between. Accordingly, and in one embodiment, capacitor C has been formed directly against vertically-thinned silicon 14, with such vertically-thinned silicon comprising a storage-node electrode 33 of capacitor C. Example second capacitor electrodes 34 of multiple capacitors C are directly electrically coupled with one another. Example first capacitor electrode 33 is directly electrically coupled to and/or comprises part of first source/drain region 23. Example memory cells MC individually comprise one horizontal transistor T and one capacitor C.

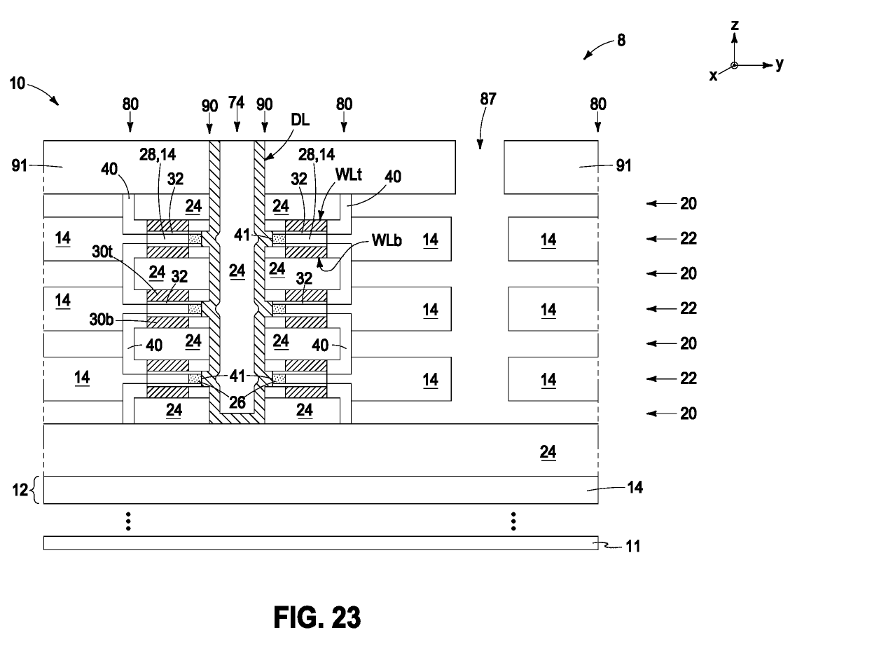

Alternate example processing in forming first capacitor storage node 33 to comprise a sideways-container shape or construction is next described with reference to FIGS. 23-25 as an alternate to the processing shown by FIGS. 21 and 22.

Referring to FIG. 23, several processing steps have occurred from that shown by FIG. 20. Silicon-germanium material 19 (no longer shown) has been removed from capacitor side 80 (e.g., through capacitor trench 87). Silicon 14 in individual silicon tiers 22 comprises a top, a bottom, and a capacitor-trench end (an end proximate and exposed to capacitor trench 87) extending between the top and bottom (e.g., analogous to surfaces 21, 31, and 41 in FIG. 6). Then, through capacitor trench 87, silicon 14 in individual silicon tiers 22 was oxidized to form silicon dioxide (not shown) on the top, the bottom, and the capacitor-trench end of the silicon, with the silicon dioxide being horizontally thicker (e.g., T_{H} in FIG. 9) on the capacitor-trench end than it is vertically thick (e.g., T_{V} in FIG. 9) on each of the top and the bottom (e.g., analogous to FIGS. 8 and 9). Silicon 14 could have been thinned prior the oxidation (e.g., as was shown by FIG. 7 with respect to digitline trench 74). Regardless, then all of the silicon dioxide was removed from the top and the bottom to leave at least some silicon dioxide on the capacitor-trench end (e.g., analogous to FIGS. 10 and 11). Then, and through the capacitor-trench, the silicon was etched from the top and the bottom while the capacitor-trench end is at least initially masked with the silicon dioxide to vertically thin the silicon in the individual silicon tiers (e.g., analogous to FIGS. 12 and 13). In one embodiment and as effectively shown, the silicon dioxide that was masking the capacitor end of the thinned silicon was removed (e.g., analogous to FIGS. 14 and 15, or by going directly from the processing shown by FIGS. 10 and 11 to that shown by FIGS. 14 and 15 in a single processing step as described above). Some of silicon 14 might be removed from the capacitor end of such silicon when removing such silicon dioxide (as shown). As shown, such has thereby increased the vertical height of the void-spaces created initially by the removal of silicon-germanium material 19, ideally without significantly reducing the horizontal length of remaining silicon 14 which will be used to define horizontal length of first capacitor electrodes 33 (not yet shown).

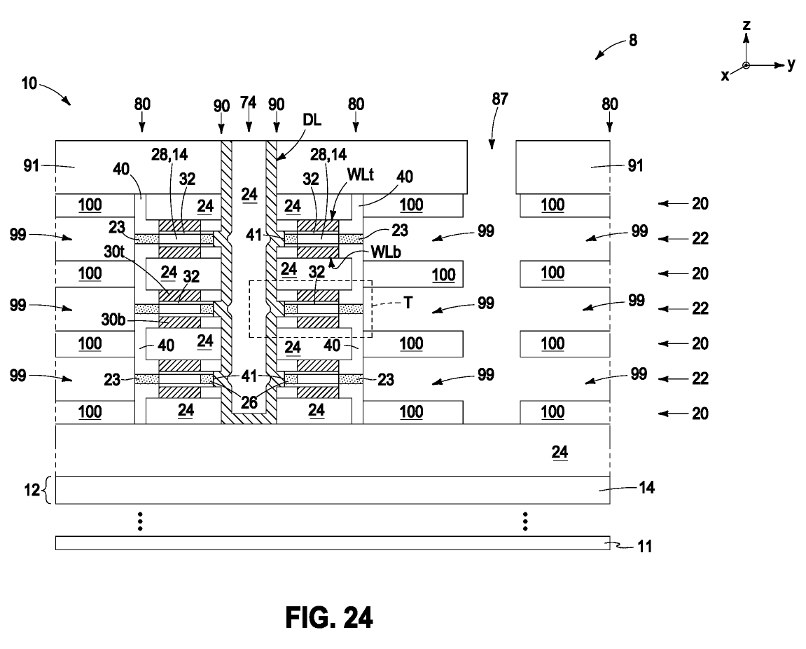

Referring to FIG. 24, several processing steps have occurred from those shown by FIG. 23. Insulative material 100 has been formed in the enlarged void-spaces. By way of example, such may comprise a thin silicon nitride layer having silicon dioxide formed thereover (neither being shown/designated) within capacitor trench 87 and the enlarged void-spaces. Such was then removed from capacitor trench 87 followed by removal of the thin silicon nitride layer from the ends of silicon 14 to expose such silicon. This was followed by removal of all of the silicon 14 that was thinned (such thereby no longer being shown), thereby forming cavities 99. This was followed by conductively doping the end of remaining silicon 14 (e.g., by gas diffusion doping) to form capacitor-side first source/drain regions 23, with a channel region 28/14 being horizontally between first and second source/drain regions 23 and 26, thus forming individual horizontal transistors T.

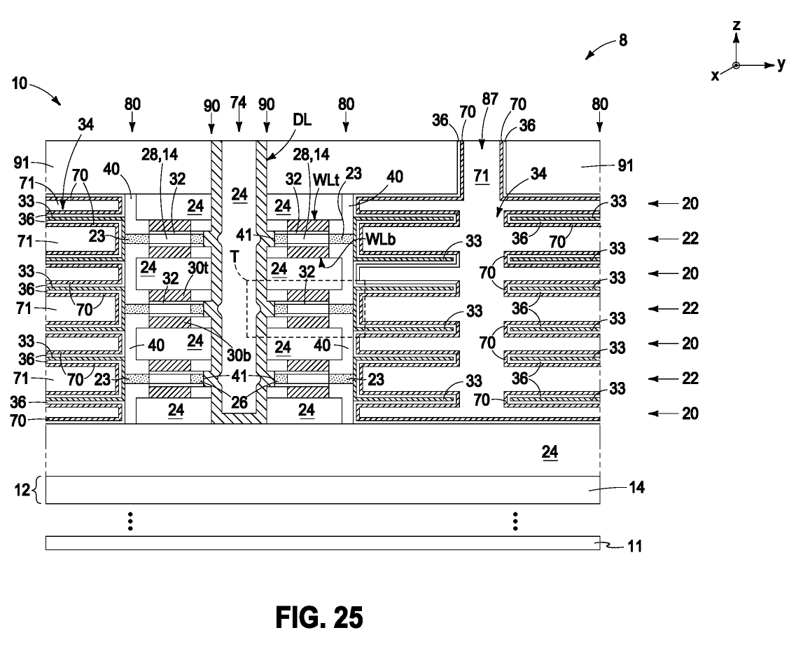

Referring to FIG. 25, several processing steps have occurred. First capacitor electrodes 33 have individually been formed in cavities 99 (no longer shown), the horizontal length of first capacitor electrodes 33 having been defined by the horizontal length of the previously removed vertically-thinned silicon, and comprising a sideways-container shape. Such were formed by conformal deposition of the conductive material making up first capacitor electrodes 33. Such was then etched back laterally to remove such from being interconnected vertically, and thus forming separate first capacitor electrodes 33. This was followed by laterally etching back insulative material 100 (no longer shown) to fully expose outer sides (upper and lower) of the sideways-container shapes and leave vertical space between immediately-adjacent first capacitor electrodes 33. Such was followed by forming second capacitor electrode 34 (e.g., comprising conductive metal material 70 and conductively-doped polysilicon 71). Again, any other attribute as described above with respect to thinned silicon 14 on digitline side 90 may apply to thinned silicon 14 on capacitor side 80.

Capacitors C or portions thereof, digitlines DL or portions thereof, and their respective trenches 87, 74 may be formed in any order relative one another, including some simultaneously. Further, and by way of example only, masking of silicon trench ends while thinning silicon 14 may occur on either and only one of capacitor side 80 or digitline side 90. Alternately, and by way of example only where masking of silicon trench ends occurs on each of capacitor side 80 and digitline side 90 as described above, such masking and silicon thinning from the tops and bottoms may occur at the same time.

In some embodiments, a method used in forming memory circuitry (e.g., 8) comprises forming a stack (e.g., 18) comprising vertically-alternating silicon tiers (e.g., 22) and intervening tiers (e.g., 20). A horizontally-elongated trench (e.g., 74 or 87) extends vertically through the stack. Silicon (e.g., 14) in individual of the silicon tiers comprises a top (e.g., 21), a bottom (e.g., 31), and a trench end (e.g., 41) extending between the top and the bottom. The intervening tiers individually comprise void-space (e.g., 95) that extends horizontally to the trench. Through the trench, the silicon is oxidized in the individual silicon tiers to form silicon dioxide (e.g., 24) on the top, the bottom, and the trench end of the silicon. The silicon dioxide is horizontally thicker (e.g., T_{H}) on the trench end than it is vertically thick (e.g., T_{V}) on each of the top and the bottom. All of the silicon dioxide is removed from the top and the bottom to leave at least some of the silicon dioxide on the trench end (e.g., FIGS. 10 and 11). After such removing and through the trench, the silicon is etched from the top and the bottom while the trench end is masked with the silicon dioxide to vertically thin the silicon in the individual silicon tiers (e.g., FIGS. 12 and 13). Any other attribute(s) or aspect(s) as shown and/or described herein with respect to other embodiments may be used.

In some embodiments, a method used in forming memory circuitry (e.g., 8) comprises forming a stack (e.g., 18) comprising vertically-alternating semiconductive tiers (e.g., 22) and intervening tiers (e.g., 20). A horizontally-elongated trench (e.g., 74 or 87) extends vertically through the stack. Semiconductive material (e.g., 14, regardless of whether silicon) in individual of the semiconductive tiers comprises a top (e.g., 21), a bottom (e.g., 31), and a trench end (e.g., 41) extending between the top and the bottom. The intervening tiers individually comprise void-space (e.g., 95) that extends horizontally to the trench. The trench end in the individual semiconductive tiers is masked (regardless of how or with what material) to leave the top and the bottom unmasked. Through the trench, the semiconductive material is removed (e.g., by etching) from the unmasked top and the unmasked bottom while the trench end is at least initially masked to vertically thin the semiconductive material in the individual semiconductive tiers.

In one embodiment, the masking comprises forming masking material (e.g., 24, regardless of whether silicon dioxide) over the top, the bottom, and the trench end of the semiconductive material (e.g., regardless of thicknesses relative one another). Then, all of the masking material is removed from the top and the bottom to leave at least some of the masking material on the trench end (e.g., FIGS. 10 and 11). In one such embodiment, the masking material is initially formed to be horizontally thicker on the trench end (e.g., T_{H}) than it is vertically thick on each of the top and the bottom (e.g., T_{V}).

In one embodiment, the masking is with masking material (e.g., 24, regardless of whether silicon dioxide). Such masking material is removed after removing the semiconductive material from the unmasked top and the unmasked bottom while the trench end is masked, with the removing of the masking material removing some of the semiconductive material from the trench end (e.g., FIGS. 14 and 15).

In one embodiment, some of the semiconductive material is removed from the top and the bottom before masking the trench end (e.g., FIG. 7).

Any other attribute(s) or aspect(s) as shown and/or described herein with respect to other embodiments may be used.

In prior processes where silicon is vertically thinned to a desired target thickness of the source/drain and channel regions, undesired significant etching can also occur from the trench ends of the silicon. This undesirably reduces the horizontal length of the thinned silicon as well as adds horizontal space between immediately-horizontally-y-direction-adjacent transistors, thus reducing circuit density. Masking the trench ends of the silicon while vertically etching from the tops and bottoms of the silicon may alleviate such issues.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of a vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor’s channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being "directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming a stack comprising vertically-alternating semiconductive tiers and intervening tiers. A horizontally-elongated trench extends vertically through the stack. Semiconductive material in individual of the semiconductive tiers comprises a top, a bottom, and a trench end extending between the top and the bottom. The intervening tiers individually comprise void-space that extends horizontally to the trench. The trench end in the individual semiconductive tiers is masked to leave the top and the bottom unmasked. Through the trench, the semiconductive material is removed from the unmasked top and the unmasked bottom while the trench end is at least initially masked to vertically thin the semiconductive material in the individual semiconductive tiers.

In some embodiments, a method used in forming memory circuitry comprises forming a stack comprising vertically-alternating silicon tiers and intervening tiers. A horizontally-elongated trench extends vertically through the stack. Silicon in individual of the silicon tiers comprises a top, a bottom, and a trench end extending between the top and the bottom. The intervening tiers individually comprise void-space that extends horizontally to the trench. Through the trench, the silicon in the individual silicon tiers is oxidized to form silicon dioxide on the top, the bottom, and the trench end of the silicon. The silicon dioxide is horizontally thicker on the trench end than it is vertically thick on each of the top and the bottom. All of the silicon dioxide is removed from the top and the bottom to leave at least some of the silicon dioxide on the trench end. After such removing and through the trench, the silicon is etched from the top and the bottom while the trench end is at least initially masked with the silicon dioxide to vertically thin the silicon in the individual silicon tiers.

In some embodiments, a method used in forming memory circuitry comprises forming a stack comprising vertically-alternating silicon tiers and intervening tiers. The silicon tiers comprise part of horizontal transistors in a finished construction of the memory circuitry. Individual memory cells in the finished construction comprising one of the horizontal transistors. A capacitor is electrically coupled to one source/drain region of the one horizontal transistor and part of a digitline that is electrically coupled to another source/drain region of the one horizontal transistor. A horizontally-elongated digitline trench extends vertically through the stack. Silicon in individual of the silicon tiers comprises a top, a bottom, and a digitline-trench end extending between the top and the bottom. The intervening tiers individually comprise void-space that extends horizontally to the digitline trench. Through the digitline trench, the silicon in the individual silicon tiers is oxidized to form silicon dioxide on the top, the bottom, and the digitline-trench end of the silicon. The silicon dioxide is horizontally thicker on the digitline-trench end than it is vertically thick on each of the top and the bottom. All of the silicon dioxide is removed from the top and the bottom to leave at least some of the silicon dioxide on the digitline-trench end. After the removing and through the digitline-trench, the silicon is etched from the top and the bottom while the digitline-trench end is at least initially masked with the silicon dioxide to vertically thin the silicon in the individual silicon tiers. The silicon dioxide is removed from masking the digitline-trench end and digitlines are formed in the digitline trench. Individual of the digitlines are directly against the digitline-trench end of the vertically-thinned silicon.

In some embodiments, a method used in forming memory circuitry comprises forming a stack comprising vertically-alternating silicon tiers and intervening tiers. The silicon tiers comprise part of horizontal transistors in a finished construction of the memory circuitry. Individual memory cells in the finished construction comprise one of the horizontal transistors, a capacitor electrically coupled to one source/drain region of the one horizontal transistor, and part of a digitline that is electrically coupled to another source/drain region of the one horizontal transistor. A horizontally-elongated capacitor trench extends vertically through the stack. Silicon in individual of the silicon tiers comprises a top, a bottom, and a capacitor-trench end extending between the top and the bottom. The intervening tiers individually comprise void-space that extends horizontally to the capacitor trench. Through the capacitor trench, the silicon is oxidized in the individual silicon tiers to form silicon dioxide on the top, the bottom, and the capacitor-trench end of the silicon. The silicon dioxide is horizontally thicker on the capacitor-trench end than it is vertically thick on each of the top and the bottom. All of the silicon dioxide is removed from the top and the bottom to leave at least some of the silicon dioxide on the capacitor-trench end. After the removing and through the capacitor-trench, the silicon is etched from the top and the bottom while the capacitor-trench end is at least initially masked with the silicon dioxide to vertically thin the silicon in the individual silicon tiers. The silicon dioxide is removed from masking the capacitor-trench end and the capacitor is formed in the capacitor trench directly electrically coupled to the one source/drain region of the one horizontal transistor.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming a stack comprising vertically-alternating semiconductive tiers and intervening tiers, a horizontally-elongated trench extending vertically through the stack; semiconductive material in individual of the semiconductive tiers comprising a top, a bottom, and a trench end extending between the top and the bottom; the intervening tiers individually comprising void-space that extends horizontally to the trench;
masking the trench end in the individual semiconductive tiers to leave the top and the bottom unmasked; and
through the trench, removing the semiconductive material from the unmasked top and the unmasked bottom while the trench end is at least initially masked to vertically thin the semiconductive material in the individual semiconductive tiers.

2. The method of claim 1 wherein the masking comprises:
forming masking material over the top, the bottom, and the trench end of the semiconductive material; and
removing all of the masking material from the top and the bottom to leave at least some of the masking material on the trench end.

3. The method of claim 2 wherein the masking material is initially formed to be horizontally thicker on the trench end than it is vertically thick on each of the top and the bottom.

4. The method of claim 1 wherein the masking is with masking material; and
removing all of the masking material from the trench end during or after removing the semiconductive material from the unmasked top and the unmasked bottom.

5. The method of claim 4 wherein the removing of the semiconductive material comprises etching using an etching chemistry and the removing of the masking material comprises etching using the etching chemistry, the etching of the masking material to remove all remaining of it from being over the trench end occurring during a latter part of the etching of the semiconductive material from the unmasked top and the unmasked bottom using the etching chemistry.

6. The method of claim 4 wherein the removing of the semiconductive material comprises etching using a first etching chemistry and the removing of the masking material from the trench end comprises etching using a second etching chemistry that is different from the first etching chemistry, the etching of at least a majority of the masking material from the trench end occurring after the etching of at least a majority of the semiconductive material to vertically thin it.

7. The method of claim 4 wherein the removing all of the masking material from the trench end removes some of the semiconductive material from the trench end.

8. The method of claim 1 comprising removing some of the semiconductive material from the top and the bottom before masking the trench end.

9. A method used in forming memory circuitry, comprising:
forming a stack comprising vertically-alternating silicon tiers and intervening tiers, a horizontally-elongated trench extending vertically through the stack; silicon in individual of the silicon tiers comprising a top, a bottom, and a trench end extending between the top and the bottom; the intervening tiers individually comprising void-space that extends horizontally to the trench;
through the trench, oxidizing the silicon in the individual silicon tiers to form silicon dioxide on the top, the bottom, and the trench end of the silicon; the silicon dioxide being horizontally thicker on the trench end than it is vertically thick on each of the top and the bottom;
removing all of the silicon dioxide from the top and the bottom to leave at least some of the silicon dioxide on the trench end; and
after the removing and through the trench, etching the silicon from the top and the bottom while the trench end is at least initially masked with the silicon dioxide to vertically thin the silicon in the individual silicon tiers.

10. The method of claim 9 wherein the silicon dioxide is formed to be at least 1.2 times horizontally thicker on the trench end than it is vertically thick on each of the top and the bottom before the removing all.

11. The method of claim 10 wherein the silicon dioxide is formed to be at least 1.4 times horizontally thicker on the trench end than it is vertically thick on each of the top and the bottom before the removing all.

12. The method of claim 11 wherein the silicon dioxide is formed to be at least 1.8 times horizontally thicker on the trench end than it is vertically thick on each of the top and the bottom before the removing all.

13. The method of claim 9 wherein the oxidizing comprises wet oxidation.

14. The method of claim 9 wherein the oxidizing comprises dry oxidation.

15. The method of claim 9 comprising etching away all of the silicon dioxide from the trench end during or after the etching of the silicon from the top and the bottom, the etching away all of the silicon dioxide from the trench end etching some of the silicon from the trench end.

16. A method used in forming memory circuitry, comprising:
forming a stack comprising vertically-alternating silicon tiers and intervening tiers, the silicon tiers comprising part of horizontal transistors in a finished construction of the memory circuitry; individual memory cells in the finished construction comprising one of the horizontal transistors, a capacitor electrically coupled to one source/drain region of the one horizontal transistor, and part of a digitline that is electrically coupled to another source/drain region of the one horizontal transistor; a horizontally-elongated digitline trench extending vertically through the stack; silicon in individual of the silicon tiers comprising a top, a bottom, and a digitline-trench end extending between the top and the bottom; the intervening tiers individually comprising void-space that extends horizontally to the digitline trench;
through the digitline trench, oxidizing the silicon in the individual silicon tiers to form silicon dioxide on the top, the bottom, and the digitline-trench end of the silicon; the silicon dioxide being horizontally thicker on the digitline-trench end than it is vertically thick on each of the top and the bottom;
removing all of the silicon dioxide from the top and the bottom to leave at least some of the silicon dioxide on the digitline-trench end;
after the removing and through the digitline-trench, etching the silicon from the top and the bottom while the digitline-trench end is at least initially masked with the silicon dioxide to vertically thin the silicon in the individual silicon tiers; and
removing the silicon dioxide from masking the digitline-trench end and forming digitlines in the digitline trench, individual of the digitlines being directly against the digitline-trench end of the vertically-thinned silicon.

17. The method of claim 16 wherein the silicon dioxide is formed to be at least 1.4 times horizontally thicker on the digitline-trench end than it is vertically thick on each of the top and the bottom before the removing all.

18. The method of claim 16 wherein the removing the silicon dioxide from masking the digitline-trench end removes some of the silicon from the digitline-trench end.

19. The method of claim 16 wherein the removing of the silicon dioxide from masking the digitline-trench end occurs during a latter part of the etching of the silicon to vertically thin it in the individual silicon tiers.

20. A method used in forming memory circuitry, comprising:
forming a stack comprising vertically-alternating silicon tiers and intervening tiers, the silicon tiers comprising part of horizontal transistors in a finished construction of the memory circuitry; individual memory cells in the finished construction comprising one of the horizontal transistors, a capacitor electrically coupled to one source/drain region of the one horizontal transistor, and part of a digitline that is electrically coupled to another source/drain region of the one horizontal transistor; a horizontally-elongated capacitor trench extending vertically through the stack; silicon in individual of the silicon tiers comprising a top, a bottom, and a capacitor-trench end extending between the top and the bottom; the intervening tiers individually comprising void-space that extends horizontally to the capacitor trench;
through the capacitor trench, oxidizing the silicon in the individual silicon tiers to form silicon dioxide on the top, the bottom, and the capacitor-trench end of the silicon; the silicon dioxide being horizontally thicker on the capacitor-trench end than it is vertically thick on each of the top and the bottom;
removing all of the silicon dioxide from the top and the bottom to leave at least some of the silicon dioxide on the capacitor-trench end;
after the removing and through the capacitor-trench, etching the silicon from the top and the bottom while the capacitor-trench end is at least initially masked with the silicon dioxide to vertically thin the silicon in the individual silicon tiers; and
removing the silicon dioxide from masking the capacitor-trench end and forming the capacitor in the capacitor trench directly electrically coupled to the one source/drain region of the one horizontal transistor.

21. The method of claim 20 comprising forming the capacitor directly against the vertically-thinned silicon, the vertically-thinned silicon comprising a storage-node electrode of the capacitor.

22. The method of claim 20 comprising removing all of the vertically-thinned silicon before forming the capacitor and forming the capacitor to comprise a storage-node electrode of a sideways-container shape.

23. The method of claim 20 wherein the silicon dioxide is formed to be at least 1.4 times horizontally thicker on the capacitor-trench end than it is vertically thick on each of the top and the bottom before the removing all.

24. The method of claim 20 wherein the removing the silicon dioxide from masking the capacitor-trench end removes some of the silicon from the capacitor-trench end.
